(19) United States
(12) Patent Application Publication
(10) Pub. No.: US 2025/0058379 A1
(43) Pub. Date: Feb. 20, 2025

(54) METHOD OF PREPARING IRIDIUM NANOCRYSTAL

(71) Applicant: PetroChina Company Limited, Beijing (CN)

(72) Inventors: Yanfei WANG, Beijing (CN); Yinglong YU, Beijing (CN); Chenyi SHAO, Beijing (CN); Chuan LONG, Beijing (CN); Qinfeng ZHAO, Beijing (CN); Jingjing WANG, Beijing (CN); Yeheng HE, Beijing (CN); Qingxun LI, Beijing (CN)

(21) Appl. No.: 18/938,081

(22) Filed: Nov. 5, 2024

Related U.S. Application Data
(63) Continuation of application No. PCT/CN2023/130601, filed on Nov. 9, 2023.

(30) Foreign Application Priority Data
Dec. 13, 2022 (CN) 202211595336.8

(51) Int. Cl. B22F 9/24; B22F 1/054; B22F 1/07; B22F 9/00; B82Y 30/00; B82Y 40/00

(52) U.S. Cl. CPC B22F 9/24; B22F 1/054; B22F 1/07; B22F 9/002; B22F 2009/245; B22F 2201/10; B22F 2301/25; B22F 2998/10; B82Y 30/00; B82Y 40/00

(57) ABSTRACT

The present application provides a preparation method for iridium nanocrystal, including the following steps: mixing an iridium salt, an alcohol solvent and a centrifugal waste liquid to form a mixed solution, and adding an alkali solution in an inert atmosphere for a heating reaction. After centrifugation, an iridium nanocrystal is obtained. The centrifugal waste liquid is a waste liquid produced in the pre-synthesis process of iridium nanocrystal. The preparation method can shorten the reaction time, and the obtained iridium nanocrystal has the advantages of high yield and low cost.

### CROSS-REFERENCE TO RELATED APPLICATION

This present application is a continuation of International Application No. PCT/CN2023/130601, filed on Nov. 9, 2023, which claims priority to Chinese Patent Application No. 202211595336.8 filed on Dec. 13, 2022. The disclosures of the aforementioned application are hereby incorporated by reference in their entireties.

### TECHNICAL FIELD

The present application belongs to the technical field of electrochemistry and, in particular, a method of preparing an iridium nanocrystal.

### BACKGROUND

Hydrogen production by water electrolysis is a main way of hydrogen production from renewable energy sources. Proton exchange membrane (PEM) hydrogen production by water electrolysis can work under high current density, which has the advantages of small volume, high efficiency and high purity of produced hydrogen; and can be used widely. Hydrogen production by water electrolysis needs a catalyst to reduce a potential of electrochemical reaction. The catalytic activity and cost of catalyst of PEM water electrolysis anode is one of the important factors restricting the development of hydrogen production by PEM water electrolysis.

Compared with non-noble metal catalyst, such as nickel, cobalt, and iron, iridium (Ir) catalyst has higher activity in acidic oxygen evolution reaction, thus iridium catalyst is considered to be the most ideal catalyst of PEM water electrolysis anode. Iridium has a low homogeneous nucleation energy barrier, which directly leads to the tendency of iridium atom to self-nucleate and grow into a small particle during the synthesis of iridium catalyst. Due to a small size of small particle, it is difficult to achieve separation, which is not conducive to improving the utilization rate of iridium nanocrystals; and iridium resource is scarce, expensive price and high cost.

At present, by doping and loading other non-noble metal materials, the catalytic activity of iridium nanocrystals is improved and the cost of iridium nanocrystals is reduced. However, the improvement degree of the catalytic activity and cost of iridium nanocrystals is far from meeting the demand. Therefore, how to obtain iridium nanocrystals with high catalytic activity and low cost is a long-term research topic in the art.

### SUMMARY

The present application provides a preparation method for an iridium nanocrystal. Recycling of the waste liquid produced by the pre-synthesis of iridium nanocrystal can shorten the reaction time. It is possible to prepare iridium nanocrystal with high catalytic activity, and have the advantages of high yield, low cost, ect.

The present application provides a preparation method for an iridium nanocrystal, including the following steps:
mixing an iridium salt, an alcohol solvent and a centrifugal waste liquid to form a mixed solution, and adding an alkali solution in an inert atmosphere for a heating reaction, centrifuging to obtaining an iridium nanocrystal, where the heating reaction is performed under a condition of a temperature of 140-220° C. and a time not exceeding 6 h; a volume of the centrifugal waste liquid is 10-50% of a volume of the mixed solution; and
the centrifugal waste liquid is a waste liquid produced by a pre-synthesis process of the iridium nanocrystal.

According to an embodiment of the present application, in the inert atmosphere, the mixed solution is heated to 120-220° C. and then the alkali solution is added.

According to an embodiment of the present application, the heating reaction has a time of 1-5 h.

According to an embodiment of the present application, the heating reaction has a time of 1.5-2 h.

According to an embodiment of the present application, the volume of the centrifugal waste liquid is 15-40% of the volume of the mixed solution.

According to an embodiment of the present application, a mass content of the iridium salt in the mixed solution is 0.02%-0.1%.

According to an embodiment of the present application, an average particle size of the iridium nanocrystal is 5-60 nm.

According to an embodiment of the present application, the centrifugal waste liquid is a waste liquid produced by a primary synthesis process of the iridium nanocrystal.

According to an embodiment of the present application, the iridium salt includes at least one of iridium trichloride, iridium tetrachloride, chloroiridic acid and iridium acetate.

According to an embodiment of the present application, the volume of the centrifugal waste liquid is 10-50% of the volume of the mixed solution.

According to an embodiment of the present application, a molar ratio of the alcohol solvent to the iridium salt is (8000-14000):1.

According to an embodiment of the present application, the mixed solution also includes an organic ligand, and the organic ligand includes at least one of ethylenediamine, polyacrylamide, citric acid and malic acid.

According to an embodiment of the present application, a molar ratio of the organic ligand to the iridium salt is (0.05-5):1.

According to an embodiment of the present application, the heating reaction is performed under a condition of a temperature of 140-220° C. and a time not exceeding 6 h.

The implementation of the present application has at least the following beneficial effects:
the present application provides a method of preparing an iridium nanocrystal, where during the pre-synthesis process of iridium nanocrystal, the centrifugal waste liquid produced contains the alcohol solvent and an iridium precursor that has not been separated by centrifugation. In the present application, the centrifugal waste liquid produced in the pre-synthesis process of iridium nanocrystal is recycled, and the iridium salt, the alcohol solvent and the centrifugal waste liquid are mixed for reaction, which can fully make use of the iridium precursor in the mixed solution and improve the synthesis yield of iridium nanocrystal. The preparation method can shorten the heating reaction time. At the same time, it can realize the efficient reuse of the iridium precursor in the centrifugal waste liquid, and greatly reduce the production cost. In addition, the preparation method also has the advantages of simple processing process and easy operation, which is conducive to industrial production and application.

### BRIEF DESCRIPTION OF DRAWINGS

FIG. 1 is a transmission electron microscope (TEM) image of iridium nanocrystal S1 in Example 1 of the present application.

FIG. 2 is a TEM image of iridium nanocrystals S2 in Example 2 of the present application.

FIG. 3 is a TEM image of iridium nanocrystals S11 in Comparative example 1 of the present application.

FIG. 4 is a TEM image of the iridium nanocrystals S12 in Comparative example 2 of the present application.

FIG. 5 is an oxygen evolution reaction polarization curve graph of iridium nanocrystal in Example 2 and Comparative example 1.

### DESCRIPTION OF EMBODIMENTS

The specific embodiments listed below are only intended to describe the principles and characteristics of the present application, and the examples given are only used to explain the present application, not to limit the scope of the present application. Based on the embodiments of the present application, all other embodiments obtained by ordinary skilled persons in the field without creative labor fall within the protection scope of the present application.

The method of preparing an iridium nanocrystal provided in the present application includes: mixing an iridium salt, an alcohol solvent and a centrifugal waste liquid to form a mixed solution, and adding an alkali solution in an inert atmosphere for a heating reaction, and centrifuging to obtain an iridium nanocrystal; where the heating reaction is performed under a condition of a temperature of 140-220° C. and a time not exceeding 6 h; a volume of the centrifugal waste liquid is 10-50% of a volume of the mixed solution; and the centrifugal waste liquid is a waste liquid produced by the pre-synthesis process of iridium nanocrystal.

In the synthesis process of iridium nanocrystal, the centrifugal waste liquid produced contains the iridium precursor that has not been separated by centrifugation and the alcohol solvent, and thus the cost of waste disposal is high. Through research, the applicant found that introducing the centrifugal waste liquid produced in the pre-synthesis process of iridium nanocrystal into the synthesis of iridium nanocrystal can not only realize the recycling of the centrifugal waste liquid, thereby reducing the loss of noble metal iridium, and reducing the production cost, but also make full use of the iridium source in the mixed solution, thereby improving the synthesis yield of iridium nanocrystal. In addition, the centrifugal waste liquid can also provide part of the solvent, reducing the usage amount of fresh alcohol solvent, and further reducing the production cost.

In the present application, a preparation process of iridium nanocrystal includes at least a primary synthesis and a secondary synthesis, and the primary synthesis is a pre-synthesis of the secondary synthesis. The centrifugal waste liquid used in the secondary synthesis is a waste liquid produced in the primary synthesis of iridium nanocrystal. Since the centrifugal waste liquid contains the unreacted ethylene glycol and iridium precursor, recycling them not only solves the problem of environmental pollution due to pollutant discharge, but also improves the utilization rate of high value-added ethylene glycol and iridium precursor.

Synthesis of iridium nanocrystal with specific structure is an effective means to enhance its catalytic activity. An addition amount of centrifugal waste liquid will affect a structure of iridium nanocrystal. When the addition amount of centrifugal waste liquid is too large, the iridium nanocrystal is easy to aggregate, resulting in irregular shape, which is not conducive to the catalytic activity of iridium nanocrystal. When the addition amount of centrifugal waste liquid is too small, it is not conducive to the recycling of centrifugal waste liquid.

In an embodiment, a volume of the centrifugal waste liquid is 10-50% of a volume of the mixed solution, for example, 10%, 20%, 30%, 40%, 50% or a range consisting of any two of them.

In the present application, by adding the centrifugal waste liquid, the reaction rate can be increased and the reaction time can be shortened. For example, when the volume of the centrifugal waste liquid is 15% of the volume of the mixed solution, the reaction time can be reduced to 2 hours. When the volume of the centrifugal waste liquid is 40% of the volume of the mixed solution, the reaction time can be reduced to 1.5 hours. In order to improve the yield of iridium nanocrystal, in a possible implementation, the pre-synthesis is the primary synthesis.

When the pre-synthesis is the primary synthesis, the centrifugal waste liquid is the waste liquid produced in the primary synthesis of iridium nanocrystal; and the method of preparing the iridium nanocrystal at least includes:
(1) mixing a first iridium salt and a first alcohol solvent to form a first mixed solution, adding an alkali solution in an inert atmosphere, performing a first heating reaction, and performing a first centrifugation to obtain a solid phase and a centrifugal waste liquid;
(2) mixing a second iridium salt, a second alcohol solvent and the centrifugal waste liquid to form a second mixed solution, adding an alkali solution in an inert atmosphere, performing a second heating reaction, and performing a second centrifugation to obtain the iridium nanocrystal.

Where, a mass of the first iridium salt and a mass of the second iridium salt may be the same or different. In order to further improve the yield of iridium nanocrystal, in a possible implementation, it is the same.

A volume of the first mixed solution and a volume of the second mixed solution may be the same or different. In order to further improve the yield of iridium nanocrystal, in a possible implementation, it is the same.

The conditions for the first heating reaction and the second heating reaction may be the same or different.

In the present application, a mass content of the iridium salt in the mixed solution is 0.02%-0.1%, such as 0.02%, 0.05%, 0.1%, or a range consisting of any two of them.

The present application does not limit the specific type of iridium salt, for example, the iridium salt includes at least one of chloroiridic acid, iridium acetate, and iridium tetrachloride.

In the present application, the iridium salt may be first dissolved in the alcohol solvent to prepare an iridium salt solution, and then the iridium salt solution is mixed with the centrifugal waste liquid to obtain the mixed solution. Where, in the dissolution process, the air in the system is removed as much as possible by filling nitrogen to ensure that the obtained material will not be oxidized by oxygen in the air during the synthesis process. The time of filling nitrogen may be 30-60 min, and in the whole process, it is possible to perform stirring to allow the iridium salt and the alcohol solvent to mix more evenly.

In the preparation process of iridium nanocrystal, the alcohol solvent acts as a solvent on one hand and a reducing agent on the other hand to promote the reduction of the iridium salt to the iridium nanocrystal.

The present application does not limit the specific type of alcohol solvent, for example, the alcohol solvent includes at least one of ethylene glycol, diethylene glycol, and ethanol.

In order to ensure that the iridium salt can be fully reduced, the alcohol solvent is excessive relative to the iridium salt. In some embodiments, a molar ratio of the alcohol solvent to the iridium salt is (8000-14000):1, for example, 8000:1, 8100:1, 8500:1, 9500:1, 10,000:1, 11000:1, 12000:1, 14000:1, or a range consisting of any two of them.

In the present application, the mixed solution also includes an organic ligand, and the organic ligand is capable of regulating the morphology of the iridium nanocrystal by limiting the growth of the iridium nanocrystal, thereby controlling the size of the iridium nanocrystal.

The present application does not limit the specific type of the organic ligand, which may be conventional organic ligand in the art, such as a compound containing an amine group and/or a carboxylic group. Further, the organic ligand includes but is not limited to at least one of ethylenediamine, polyacrylamide, citric acid, and malic acid.

The size of iridium nanocrystal can be controlled by adjusting the added amount of organic ligand. In some embodiments, a molar ratio of the organic ligand to the iridium salt is (0.05-10):1, in a possible implementation, a molar ratio of the organic ligand to the iridium salt is (0.05-5):1, for example, 0.05:1, 0.1:1, 0.5:1, 1:1, 2:1, 3:1, 4:1, 5:1, or a range consisting of any two of them.

In the present application, the pH is adjusted by adding an alkali solution, and the added amount of alkali solution is determined according to the amount of mixed solution. When the volume of mixed solution is 90 mL, the added amount of alkali solution may be 5 mL-10 mL.

The present application does not limit the specific type of alkali solution. The alkali solution contains an alkaline compound, and includes, but is not limited to, the solution containing at least one of sodium hydroxide and potassium hydroxide.

In some embodiments, a molar ratio of the alkaline compound to the iridium salt is (0.1-1):1, for example, 0.1:1, 0.2:1, 0.4:1, 0.6:1, 0.8:1, 1:1, or a range consisting of any two of them.

Before adding the alkali solution, the mixed solution can be heated first, for example, the mixed solution can be first heated to 120° C., and then the alkali solution is added.

In the present application, the iridium salt is reduced to form the iridium nanocrystal by the heating reaction of the mixed solution added with the alkali solution. In the heating process, the air in the system is removed as much as possible by filling nitrogen to ensure that the obtained material is not oxidized by oxygen in the air during the synthesis process.

Where, the conditions for the heating reaction include: a temperature of 140-220° C., in a possible implementation, a temperature of 140-180° C., and a time not exceeding 6 h, in a possible implementation, a time not exceeding 3-4 h. The heating reaction can be carried out by a gradually heated manner, for example, by heating to 140-220° C. at a heating rate of 2° C./min. After the heating reaction is over, the temperature is cooled naturally or in a forced manner to room temperature.

The present application is not limited to centrifugation and may be a conventional centrifugation method in the art. In an embodiment of the present application, a rotational speed for centrifugation is 18,000 rpm.

The present application also includes washing and drying the solid phase obtained by centrifugation to obtain the iridium nanocrystal. In an embodiment of the present application, the iridium nanocrystal is obtained by washing the solid phase with the water several times and then vacuum drying at 90° C.

In the present application, the finally obtained iridium nanocrystal has an average particle size of 5-60 nm. The nanomaterial has excellent electrocatalytic properties such as oxygen evolution. Specifically, the iridium nanocrystal has an average particle size of 5 nm, 10 nm, 15 nm, 20 nm, 25 nm, 30 nm, 35 nm, 40 nm, 45 nm, 50 nm, 55 nm, 60 nm, or a range consisting of any two of them.

The iridium nanocrystal provided in the present application can recycle the waste liquid produced by the pre-synthesis of iridium nanocrystal; and mixing the iridium salt, the alcohol solvent and the centrifugal waste liquid for reaction, can make full use of the iridium source in the mixed solution and improve the synthesis yield of iridium nanocrystal. In addition, it is possible to realize the efficient reuse of the iridium precursor in the centrifugal waste liquid, and the centrifugal waste liquid can also provide part of the solvent, thereby reducing the use of fresh alcohol solvent, and further reducing the production cost.

Below, the method of preparing the iridium nanocrystal of the present application is described in detail by specific examples.

Each raw material of following Examples and Comparative examples is as follows:
chloroiridic acid: a purity of 99.98%;
ethylene glycol: anhydrous grade, a purity of 99.8%;
NaOH solution: a mass concentration of 0.01 mol/L.

### Example 1

(1) 200 mg chloroiridic acid was added to 90 mL ethylene glycol to obtain an iridium salt solution, and N2 was introduced into the iridium salt solution for 60 min, keeping in N2 atmosphere and stirring properly. The solution was heated to 120° C. at a heating rate of 2° C./min, followed by injecting 10 mL NaOH solution, heating to 150° C., keeping the temperature for 3 h, and then cooling to room temperature. Then, a first solid phase and a centrifugal waste liquid were obtained by centrifugation using a high-speed centrifuge; and after the first solid phase was washed and vacuum dried at 90° C. for 24 h, an iridium nanocrystal sample was collected.

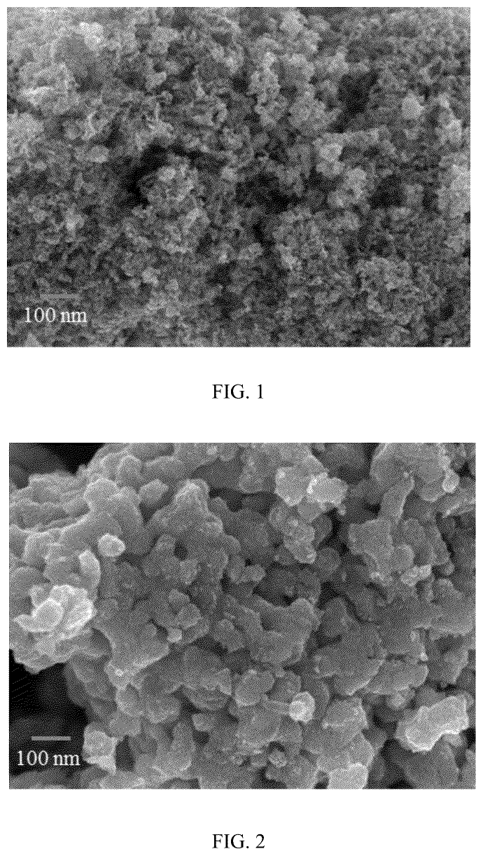

(2) 200 mg chloroiridic acid was dissolved in 10 mL ethylene glycol, with stirring during the dissolution process. After complete dissolution, the solution obtained was transferred to 60 mL ethylene glycol. 20 mL of the centrifugal waste liquid was further added, at this time a total volume of the solution being 90 mL, N2 was introduced into the solution for 60 min, keeping in N2 atmosphere and stirring properly. The solution was heated to 120° C. at a heating rate of 2° C./min, followed by adding 10 mL NaOH solution, heating to 150° C., keeping the temperature for 2 h, and then cooling to room temperature. Then, a second solid phase was collected by centrifugation using a high-speed centrifuge; and after the second solid phase was washed and vacuum dried at 90° C. for 24 h, an iridium nanocrystal sample S1 was obtained (TEM image of the iridium nanocrystal S1 was shown in FIG. 1).

### Example 2

The preparation method is basically the same as that in Example 1, except that in step (2), 200 mg chloroiridic acid is added to 50 mL ethylene glycol, with stirring during the dissolution process; after complete dissolution, 40 mL of the centrifugal waste liquid is added; and 6 mL NaOH solution is added, other conditions being unchanged. An iridium nanocrystal sample S2 is obtained (TEM image of iridium nanocrystal sample S2 is shown in FIG. 2).

### Example 3

The preparation method is basically the same as that in Example 1, except that in step (2), 200 mg chloroiridic acid and 0.08 mmol citric acid are added to 70 mL ethylene glycol, with stirring during the dissolution process; after complete dissolution, 20 mL of the centrifugal waste liquid is added, and 8 mL NaOH solution is injected, other conditions being unchanged. An iridium nanocrystal sample S3 is obtained.

### Example 4

The preparation method is basically the same as that in Example 1, except that in step (2), 200 mg chloroiridic acid and 0.08 mmol citric acid are added to 50 mL ethylene glycol, with stirring during the dissolution process; and after complete dissolution, 40 mL of the centrifugal waste liquid is added, and 6 mL NaOH solution is injected, other conditions being unchanged. An iridium nanocrystal sample S4 is obtained.

### Example 5

The preparation method is basically the same as that of Example 1, except that in step (2), 200 mg chloroiridic acid and 0.08 mmol ethylenediamine are dissolved in 70 mL ethylene glycol, with stirring during the dissolution process; after complete dissolution, 20 mL of the centrifugal waste liquid is added, and 8 mL NaOH solution is injected, other conditions being unchanged. An iridium nanocrystal sample S5 is obtained.

### Example 6

The preparation method is basically the same as that in Example 1, except that in step (2), 0.04 mmol iridium acetate is added to 70 mL ethylene glycol, with stirring during the dissolution process; after complete dissolution, 20 mL of the centrifugal waste liquid is added, 8 mL NaOH solution is injected, and the temperature of heating reaction is 160° C., other conditions being unchanged. An iridium nanocrystal sample S6 is obtained.

### Example 7

The preparation method is basically the same as that in Example 1, except that in step (2), 0.04 mmol iridium acetate and 0.08 mmol citric acid are added to 70 mL ethylene glycol, with stirring during the dissolution process; after complete dissolution, 20 mL of the centrifugal waste is added, and 8 mL NaOH solution is added, and the temperature of heating reaction is 160° C., other conditions being unchanged. An iridium nanocrystal sample S7 is obtained.

### Example 8

The preparation method is basically the same as that in Example 1, except that in step (2), 0.04 mmol iridium acetate is added to 60 mL ethylene glycol to obtain an iridium acetate solution, 0.08 mmol citric acid is dissolved in 10 mL ethylene glycol to obtain a citric acid solution, and then the iridium acetate solution is mixed with citric acid solution, with stirring during the dissolution process; after complete dissolution, 20 mL of the centrifugal waste liquid is added to the mixed solution, 8 mL NaOH solution is injected, the temperature of heating reaction is 160° C., other conditions being unchanged. An iridium nanocrystal sample S8 is obtained.

### Example 9

The preparation method is basically the same as that in Example 1, except that in step (2), 0.04 mmol iridium tetrachloride is added to 70 mL ethylene glycol, with stirring during the dissolution process; after complete dissolution, 20 mL of the centrifugal waste liquid is added, 8 mL NaOH solution is injected, and the temperature of heating reaction is 170° C., other conditions being unchanged. An iridium nanocrystal sample S9 is obtained.

### Example 10

The preparation method is basically the same as that in Example 1, except that in step (2), 0.04 mmol of iridium tetrachloride is added to 60 mL ethylene glycol to obtain an iridium acetate solution, 0.08 mmol citric acid is added to 10 mL ethylene glycol to obtain a citric acid solution, and then the iridium tetrachloride solution is mixed with the citric acid solution, with stirring during the dissolution process; after complete dissolution, 20 mL of the centrifugal waste liquid is added, 8 mL NaOH solution is injected, and the temperature of heating reaction is 170° C., other conditions being unchanged. An iridium nanocrystal sample S10 is obtained.

### Comparative Example 1

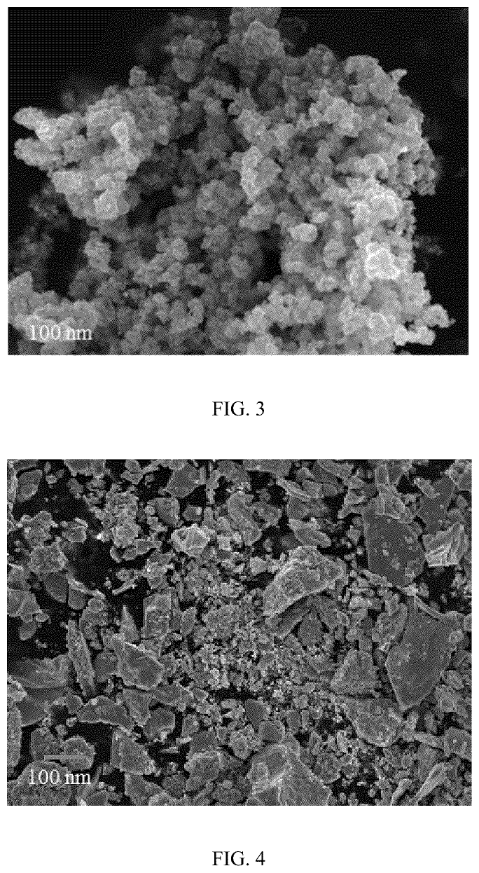

200 mg chloroiridic acid was added to 90 mL ethylene glycol to obtain an iridium salt solution, and N2 was introduced into the iridium salt solution for 60 min, keeping in N2 atmosphere and stirring properly. The solution was heated to 120° C. at a heating rate of 2° C./min, and followed by injecting 10 mL NaOH solution, heating to 150° C., keeping the temperature for 3 h, and then cooling to room temperature; Then, a first solid phase and a centrifugal waste liquid were obtained by centrifugation using a high-speed centrifuge; and after the first solid phase was washed and vacuum dried at 90° C. for 24 h, an iridium nanocrystal sample S11 was collected (TEM of S11 was shown in FIG. 3).

### Comparative Example 2

The preparation method is basically the same as that of Example 1, except that in step (2), 200 mg chloroiridic acid is added to 30 mL ethylene glycol, with intense stirring during the dissolution process; after complete dissolution, 60 mL of the centrifugal waste liquid is added, other conditions being unchanged. An iridium nanocrystal sample S12 is obtained (TEM image of S12 is shown in FIG. 4).

### Test Example

The test method for oxygen evolution reaction polarization curve includes the following:
(1) weighing 5 mg catalyst, adding 250 μL isopropyl alcohol and 250 μL nafion diluent successively, and treating with ultrasound for 30 min to make a slurry mix evenly;
(2) evenly dropping an appropriate amount of dispersed slurry onto a smooth and clean disk electrode surface, and drying it naturally to obtain a working electrode;
(3) using a three-electrode system for the test procedure, where a rotational speed of the disk electrode is 1600 RPM, and activating the catalyst by the cyclic voltammetry in a suitable voltage range until the catalyst reaches a stable state, where the measurement is carried out in the potential range of 1.23-1.60V at the scanning rate of 1 mV·s⁻¹ (relative to the reversible hydrogen electrode, RHE).

The calculation method for the yield of iridium nanocrystal: the yield is a ratio of a mass of iridium nanocrystal actually obtained to a mass of iridium nanocrystal theoretically obtained from the input of iridium salt.

The preparation raw materials of Examples and Comparative examples as well as the yield of iridium nanocrystal are shown in Table 1.

TABLE 1

| | | | Usage amount of | |
|---|---|---|---|---|
| | | | centrifugal waste liquid | Yield of iridium |
| Sample | Iridium salt | Organic ligand | mL | nanocrystal product % |
| S1 | chloroiridic acid | no | 20 | 88 |
| S2 | chloroiridic acid | no | 40 | 90 |
| S3 | chloroiridic acid | citric acid | 20 | 92 |
| S4 | chloroiridic acid | citric acid | 40 | 93 |
| S5 | chloroiridic acid | ethylenediamine | 20 | 95 |
| S6 | iridium acetate | no | 20 | 89 |
| S7 | iridium acetate | citric acid | 20 | 90 |
| S8 | iridium acetate | ethylenediamine | 20 | 92 |
| S9 | iridium | no | 20 | 87 |
| | tetrachloride | | | |
| S10 | iridium | citric acid | 20 | 88 |
| | tetrachloride | | | |
| S11 | chloroiridic acid | no | 0 | 80 |
| S12 | chloroiridic acid | no | 60 | 75 |

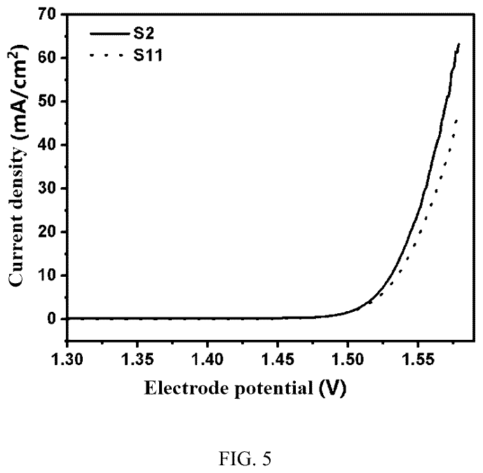

According to Table 1, it can be seen that the iridium nanocrystal provided in the present application has a higher synthesis yield, and according to FIG. 5, the iridium nanocrystal prepared in Example 2 of the present application has a higher catalytic activity.

Finally, it should be noted that the foregoing embodiments are used only to illustrate the technical solution of the present application, and not used to limit the present application. Notwithstanding the present application is described in detail by reference to the foregoing embodiments, it should be understood by persons of ordinary skill in the art that they may modify the technical solutions recorded in the foregoing embodiments, or make equivalent substitutions for some or all of the technical features thereof; such modification or substitution shall not make the essence of the corresponding technical solution depart from the scopes of the technical solutions of embodiments of the present application.

What is claimed is:

1. A preparation method for an iridium nanocrystal, comprising the following steps:
mixing an iridium salt, an alcohol solvent and a centrifugal waste liquid to form a mixed solution, and adding an alkali solution in an inert atmosphere for a heating reaction, centrifuging to obtaining an iridium nanocrystal, wherein the heating reaction is performed under a condition of a temperature of 140-220° C. and a time not exceeding 6 h; a volume of the centrifugal waste liquid is 10-50% of a volume of the mixed solution; and the centrifugal waste liquid is a waste liquid produced by a pre-synthesis process of the iridium nanocrystal.

2. The preparation method according to claim 1, wherein in the inert atmosphere, the mixed solution is heated to 120-220° C. and then the alkali solution is added.

3. The preparation method according to claim 1, wherein the heating reaction has a time of 1-5 h.

4. The preparation method according to claim 2, wherein the heating reaction has a time of 1-5 h.

5. The preparation method according to claim 1, wherein the heating reaction has a time of 1.5-2 h.

6. The preparation method according to claim 1, wherein the volume of the centrifugal waste liquid is 15-40% of the volume of the mixed solution.

7. The preparation method according to claim 1, wherein a mass content of the iridium salt in the mixed solution is 0.02%-0.1%.

8. The preparation method according to claim 1, wherein an average particle size of the iridium nanocrystal is 5-60 nm.

9. The preparation method according to claim 1, wherein the centrifugal waste liquid is a waste liquid produced by a primary synthesis process of the iridium nanocrystal.

10. The preparation method according to claim 1, wherein the iridium salt includes at least one of iridium trichloride, iridium tetrachloride, chloroiridic acid and iridium acetate.

11. The preparation method according to claim 1, wherein the alkali solution contains an alkaline compound, and a molar ratio of the alkaline compound to the iridium salt is (0.1-1):1.

12. The preparation method according to claim 1, wherein a molar ratio of the alcohol solvent to the iridium salt is (8000-14000):1.

13. The preparation method according to claim 1, wherein the mixed solution also contains an organic ligand; and the organic ligand comprises at least one of ethylenediamine, polyacrylamide, citric acid and malic acid.

14. The preparation method according to claim 1, wherein a molar ratio of the organic ligand to the iridium salt is (0.05-5):1.
